(19) United States
(12) Patent Application Publication
(10) Pub. No.: US 2024/0268175 A1
(43) Pub. Date: Aug. 8, 2024

(54) Display Panel and Display Apparatus

(71) Applicants: Chengdu BOE Optoelectronics Technology Co., Ltd., Chengdu, Sichuan (CN); BOE Technology Group Co., Ltd., Beijing (CN)

(72) Inventors: Cheng ZENG, Beijing (CN); Jaeho LEE, Beijing (CN)

(21) Appl. No.: 18/021,181

(22) PCT Filed: Mar. 31, 2022
(86) PCT No.: PCT/CN2022/084348

§ 371 Date: Feb. 14, 2023

(51) Int. Cl. H10K 59/38; H10K 59/122; H10K 59/80

(52) U.S. Cl. CPC H10K 59/38; H10K 59/122; H10K 59/877; H10K 59/878; H10K 59/879; H10K 59/8792

(57) ABSTRACT

A display panel includes a light-emitting substrate, a light extraction structure layer and a color conversion layer, the light-emitting substrate provides incident light to the light extracting structure, the light-emitting substrate includes a light-emitting device; the light extraction structure layer is between the light-emitting substrate and the color conversion layer, the light extraction structure layer is configured to form at least a portion of the incident light provided by the light-emitting substrate into collimated light, and emit it towards the color conversion layer, the light extraction structure layer includes a light extraction pattern, at least two protrusions in the light extraction pattern have different sizes; the color conversion layer is configured to convert the collimated light into light with a specific color, or to transmit the collimated light, the color conversion layer includes a first color conversion pattern, a second color conversion pattern and a light transmission pattern.

### CROSS-REFERENCE TO RELATED APPLICATIONS

The present application is a U.S. National Phase Entry of International Application PCT/CN2022/084348 having an international filing date of Mar. 31, 2022, and entitled “Display Panel and Display Apparatus”. The entire contents of the above-identified applications are hereby incorporated by reference.

### TECHNICAL FIELD

The present disclosure relates to, but is not limited to, the field of display technology, and more particularly, to a display panel and a display apparatus.

### BACKGROUND

OLED display technology has characteristics such as self-luminescence, wide viewing angle, wide color gamut, high contrast, lightness and thinness, foldability, bendability, portability, etc., and has become a key direction for research and development in the display field.

In QD (Quantum Dot) technology, semiconductor particles on the nanometer scale are used to generate light of specific frequency by applying a certain electric field or light pressure on them. A light emitting frequency is related to a diameter of the particles, so the frequency of light, that is, the color of light, can be adjusted by adjusting the diameter of the particles. R/G/B peak width at half-height of a spectrum emitted by quantum dots is narrower than that of a spectrum of a self-luminescence OLED, the spectrum is purer and the color saturation is higher.

In the QD-OLED technology, blue OLED backlight is used to excite quantum dots, so that they can generate red and green light of corresponding wavelength, thereby achieving a purpose of high color gamut and high picture quality performance. At present, in QD-OLED display devices, quantum dots cannot completely absorb the backlight emitted by the OLEDs, which affects a display effect of the display devices.

### SUMMARY

The following is a summary of subject matter described herein in detail. The summary is not intended to limit the protection scope of the claims.

In one aspect, the present disclosure provides a display panel including a light-emitting substrate, a light extraction structure layer and a color conversion layer, wherein the light-emitting substrate is configured to provide incident light to the light extraction structure, the light-emitting substrate includes at least one light-emitting device; the light extraction structure layer is located between the light-emitting substrate and the color conversion layer, the light extraction structure layer is configured to form at least a portion of the incident light provided by the light-emitting substrate into collimated light, and emit the collimated light towards the color conversion layer, the light extraction structure layer includes at least one light extraction pattern, an orthographic projection of a light extraction pattern on a plane where the display panel is located overlaps at least partially with an orthographic projection of a light-emitting device on the plane where the display panel is located, and the light extraction pattern includes multiple protrusions, at least two protrusions in the light extraction pattern have different sizes; the color conversion layer is configured to convert the collimated light into light with a specific color, or to transmit the collimated light, the color conversion layer includes at least one first color conversion pattern, at least one second color conversion pattern and at least one light transmission pattern.

In an exemplary implementation, the at least two protrusions in the light extraction pattern have different shapes.

In an exemplary implementation, a shape of the protrusions includes at least one of cone, hemisphere or pyramid.

In an exemplary implementation, the multiple protrusions in the light extraction pattern are arranged in a shape of at least one of a rectangle, a hexagon, a circle, a rhombus, a triangle and a trapezoid.

In an exemplary implementation, a part of the protrusions in the light extraction pattern are arranged along a second direction to form columns of protrusions, the columns of protrusions are arranged along a first direction, protrusions located in a same column of protrusions have a same size, protrusions located in different columns of protrusions have different sizes, and the first direction intersects with the second direction.

In an exemplary implementation, the light extraction pattern includes a first column of protrusions, a second column of protrusions and a third column of protrusions, the first column of protrusions, the second column of protrusions and the third column of protrusions are sequentially arranged along the first direction, protrusions in the first column of protrusions and protrusions in the third column of protrusions have a same size, and a height of protrusions in the second column of protrusions is greater than or less than a height of the protrusions in the first column of protrusions.

In an exemplary implementation, a shape of the orthographic projection of the light-emitting device on the plane where the display panel is located includes at least one of rectangle, rhombus, hexagon, octagon, circle, triangle and trapezoid.

In an exemplary implementation, the light-emitting substrate includes at least one first light-emitting device, at least one second light-emitting device and at least one third light-emitting device, an orthographic projection of the at least one first color conversion pattern on the plane where the display panel is located overlaps at least partially with an area where the at least one first light-emitting device is located, an orthographic projection of the at least one second color conversion pattern on the plane where the display panel is located overlaps at least partially with an area where the at least one second light-emitting device is located, and an orthographic projection of the at least one light transmission pattern on the plane where the display panel is located overlaps at least partially with an area where the at least one third light-emitting device is located.

In an exemplary implementation, the display panel further includes spacer posts disposed between the light-emitting substrate and the color conversion layer, the spacer posts are configured to reflect at least a portion of light directed towards the spacer posts towards the color conversion layer.

In an exemplary implementation, the color conversion layer includes a light blocking pattern, and an orthographic projection of the spacer posts on the plane where the display panel is located overlaps at least partially with an orthographic projection of the light blocking pattern on the plane where the display panel is located.

In an exemplary implementation, the light-emitting substrate further includes a pixel definition layer located at a periphery of the light-emitting device, and the orthographic projection of the spacer posts on the plane where the display panel is located are within an orthographic projection of the pixel definition layer on the plane where the display panel is located.

In an exemplary implementation, a cross section of each spacer post in a plane perpendicular to a plane where the light-emitting substrate is located are in a shape of a regular trapezoid or an inverted trapezoid.

In an exemplary implementation, the multiple spacer posts, along with the light extraction structure layer and the color conversion layer, form closed chambers, and a refractive index of the spacer posts is less than a refractive index of a medium in the closed chambers.

In an exemplary implementation, the display panel further includes a light dispersion layer located between the light-emitting substrate and the color conversion layer, the light dispersion layer is configured to scatter at least a portion of light directed towards the light dispersion layer to form emergent light of uniform intensity, and to emit the emergent light towards the color conversion layer.

In an exemplary implementation, the light dispersion layer includes a first matrix and additive particles disposed in the first matrix, the first matrix is made of an organic material, and the additive particles is made of oxides.

In an exemplary implementation, a diameter of the additive particles is 20 nm to 100 nm, and a mass concentration of the additive particles in the light dispersion layer is 10% to 40%.

In an exemplary implementation, the display panel further includes a reflective layer located between the light-emitting substrate and the color conversion layer, the reflective layer is configured to reflect at least a portion of light directed towards the reflective layer towards the color conversion layer.

In an exemplary implementation, the display panel further includes a light dispersion layer located between the light-emitting substrate and the color conversion layer, the light dispersion layer is configured to scatter at least a portion of light directed towards the light dispersion layer to form emergent light of uniform intensity and emit the emergent light towards the color conversion layer, and the reflective layer is disposed on one side of the light dispersion layer close to the light-emitting substrate; or the reflective layer is disposed on one side of the light dispersion layer away from the light-emitting substrate.

In an exemplary implementation, the reflective layer includes at least one high-refractive-index material layer and at least one low-refractive-index material layer, the at least one high-refractive-index material layer overlaps with the at least one low-refractive-index material layer along a direction perpendicular to the plane where the display panel is located.

In an exemplary implementation, the reflective layer is disposed on the side of the light dispersion layer close to the light-emitting substrate, the reflective layer includes n high-refractive-index material layers and m low-refractive-index material layers, n being a natural number greater than or equal to 1, m being a natural number greater than or equal to 2, m being greater than n, a surface of the reflective layer away from the light-emitting substrate is a surface of the low-refractive-index material layers away from the light-emitting substrate, and a surface of the reflective layer close to the light-emitting substrate is a surface of the low-refractive-index material layers close to the light-emitting substrate.

In an exemplary implementation, the reflective layer is disposed on the side of the light dispersion layer away from the light-emitting substrate, the reflective layer includes n high-refractive-index material layers and n low-refractive-index material layers, n being a natural number greater than or equal to 1, the surface of the reflective layer close to the light-emitting substrate is a surface of the high-refractive-index material layers close to the light-emitting substrate, and the surface of the reflective layer away from the light-emitting substrate is a surface of the low-refractive-index material layers away from the light-emitting substrate.

In an exemplary implementation, each low-refractive-index material layer includes a second matrix and hollow particles disposed in the second matrix, and a concentration of the hollow particles in the low-refractive-index material layer is 20% to 40%.

In an exemplary implementation, the low-refractive-index material layers include one of or a combination of aluminum oxide, silicon dioxide, magnesium fluoride and boron oxide.

In an exemplary implementation, the high-refractive-index material layers include one of or a combination of titanium dioxide, zirconium dioxide and silicon nitride.

In an exemplary implementation, a thickness of a high-refractive-index material layer is 60 nm to 100 nm, and a thickness of a low-refractive-index material layer is 100 nm to 150 nm.

In another aspect, the present disclosure further provides a display apparatus including the aforementioned display panel.

Other aspects may become clear upon reading and understanding of the accompanying drawings and the detailed description.

### BRIEF DESCRIPTION OF DRAWINGS

Accompanying drawings are intended to provide an understanding of technical solutions of the present application and form a part of the specification, and are used to explain the technical solutions of the present application together with embodiments of the present application, and not intended to form limitations on the technical solutions of the present application.

FIG. 1 is a schematic diagram of a planar structure of a display panel in accordance with an embodiment of the present disclosure.

FIG. 2 is a first sectional view of a display panel in accordance with an embodiment of the present disclosure.

FIG. 3 is a first schematic diagram of a planar structure of a light-emitting substrate in a display panel in accordance with an embodiment of the present disclosure.

FIG. 4 is a second schematic diagram of a planar structure of a light-emitting substrate in a display panel in accordance with an embodiment of the present disclosure.

FIG. 5 is a third schematic diagram of a planar structure of a light-emitting substrate in a display panel in accordance with an embodiment of the present disclosure.

FIG. 6 is a first schematic structural diagram of a protrusion in a display panel in accordance with an embodiment of the present disclosure.

FIG. 7 is a second schematic structural diagram of a protrusion in a display panel in accordance with an embodiment of the present disclosure.

FIG. 8 a third schematic structural diagram of a protrusion in a display panel in accordance with an embodiment of the present disclosure.

FIG. 9 is a first schematic diagram of a planar structure of a light extraction pattern in a display panel in accordance with an embodiment of the present disclosure.

FIG. 10 is a second schematic diagram of a planar structure of a light extraction pattern in a display panel in accordance with an embodiment of the present disclosure.

FIG. 11 is a second sectional view of a display panel in accordance with an embodiment of the present disclosure.

FIG. 12 is a third sectional view of a display panel in accordance with an embodiment of the present disclosure.

FIG. 13 is a fourth sectional view of a display panel in accordance with an embodiment of the present disclosure.

FIG. 14 is a fifth sectional view of a display panel in accordance with an embodiment of the present disclosure.

FIG. 15 is a schematic diagram of emergent light after being excited by quantum dots in a color conversion layer in a display panel in accordance with an embodiment of the present disclosure.

FIG. 16 is a schematic structural diagram of a low-refractive-index material layer in a display panel in accordance with an embodiment of the present disclosure.

FIG. 17 is a first simulation graph of a display panel in accordance with an embodiment of the present disclosure.

FIG. 18 is a second simulation graph of a display panel in accordance with an embodiment of the present disclosure.

FIG. 19 is a schematic diagram of a planar structure of a light-emitting device in a display panel in accordance with an embodiment of the present disclosure.

### DETAILED DESCRIPTION

In order to make objects, technical solutions and advantages of the present disclosure more clear, embodiments of the present disclosure will be described below in detail in combination with the drawings. It should be noted that implementations may be practiced in a number of different forms. Those of ordinary skills in the art may readily understand the fact that implementations and contents may be transformed into various forms without departing from the purpose and scope of the present disclosure. Therefore, the present disclosure should not be interpreted as being limited to the contents recorded in following implementations only. The embodiments in the present disclosure and features in the embodiments can be randomly combined with each other if there is no conflict.

Sometimes for the sake of clarity, sizes of various constituent elements, thicknesses of layers or regions in the drawings may be exaggerated. Therefore, one implementation of the present disclosure is not necessarily limited to the sizes, and the shapes and sizes of various components in the drawings do not reflect actual scales. In addition, the drawings schematically illustrate ideal examples, and one implementation of the present disclosure is not limited to the shapes or numerical values shown in the drawings.

Ordinal numerals such as “first”, “second”, “third” and the like in the specification are set to avoid confusion between the constituent elements, but not to set a limit in quantity.

For convenience, terms such as “middle”, “upper”, “lower”, “front”, “back”, “vertical”, “horizontal”, “top”, “bottom”, “inside”, “outside” and the like indicating orientation or position relationships are used in the specification to illustrate position relationships between the constituent elements with reference to the drawings, and are intended to facilitate description of the specification and simplification of the description, but not to indicate or imply that the mentioned device or element must have a specific orientation or be constructed and operated in a specific orientation, therefore, they should not be understood as limitations on the present disclosure. The position relationships between the constituent elements are appropriately changed according to directions according to which the constituent elements are described. Therefore, wordings used in the specification are not limited and appropriate substitutions may be made according to situations.

Unless otherwise specified and defined explicitly, terms “installed”, “coupled” and “connected” should be understood in a broad sense in the specification. For example, a connection may be a fixed connection, a detachable connection or an integrated connection, or may be a mechanical connection or an electrical connection, or may be a direct connection, an indirect connection through intermediate components, or internal communication between two components. For those skilled in the art, specific meanings of the above terms in the present disclosure can be understood according to specific situations.

In the specification, a transistor refers to an element which at least includes three terminals, a gate electrode, a drain electrode and a source electrode. The transistor has a channel region between the drain electrode (drain electrode terminal, drain region or drain) and the source electrode (source electrode terminal, source region or source), and a current can flow through the drain electrode, the channel region and the source electrode. In the specification, the channel region refers to a region which the current flows mainly through.

In the specification, the first electrode may be a drain electrode and the second electrode may be a source electrode, or the first electrode may be a source electrode and the second electrode may be a drain electrode. In a case that transistors with opposite polarities are used or a case that a current direction is changed during circuit operation, functions of the “source electrode” and the “drain electrode” are sometimes interchangeable. Therefore, the “source electrode” and the “drain electrode” are interchangeable in the specification.

In the specification, “electrical connection” includes a case where the constituent elements are connected together through an element with a certain electrical effect. The “element with the certain electrical effect” is not particularly limited as long as electrical signals can be sent and received between the connected constituent elements. Examples of the “element with the certain electrical action” not only include an electrode and a wiring, but also include a switching element such as a transistor, a resistor, an inductor, a capacitor, or another element with one or more functions, etc.

In the specification, “parallel” refers to a state in which an angle formed by two straight lines is above −10° and below 10°, and thus also includes a state in which the angle is above −5° and below 5°. In addition, “vertical” refers to a state in which an angle formed by two straight lines is above 80° and below 100°, and thus also includes a state in which the angle is above 85° and below 95°.

In the specification, “film” and “layer” are interchangeable. For example, sometimes “conductive layer” may be replaced with “conducting film”. Similarly, sometimes “insulating film” may be replaced with “insulating layer”.

“About” in the present disclosure means that a boundary is defined not strictly and numerical values in process and measurement error ranges are allowed

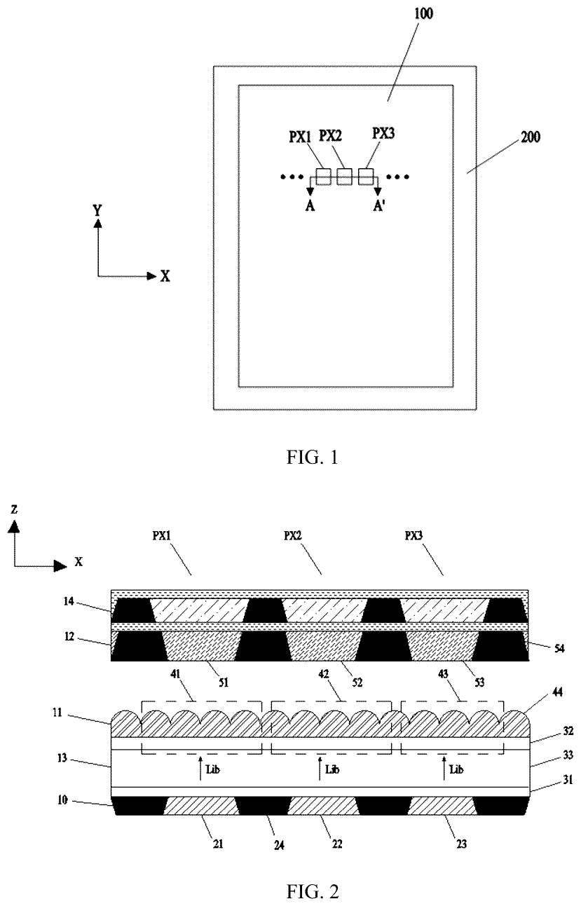

FIG. 1 is a schematic diagram of a planar structure of a display panel in accordance with an embodiment of the present disclosure. In an exemplary implementation, as shown in FIG. 1, the display panel may include a display area 100 and a non-display area 200. The display area 100 is configured to display images. The display area 100 includes multiple sub-pixels PX arranged regularly, and the sub-pixels PX are configured to emit light. For example, the display area 100 includes multiple first sub-pixels PX1, multiple second sub-pixels PX2 and multiple third sub-pixels PX3, which are arranged regularly. The first sub-pixels PX1 may be red (R) sub-pixels, the second sub-pixels PX2 may be green (G) sub-pixels, and the third sub-pixels PX3 may be blue (B) sub-pixels. The display panel may provide images by the multiple sub-pixels PX in the display area 100. The images are not displayed in the non-display area 200, and the non-display area 200 may completely or partially surround the display area 100. The non-display area 200 may include a driver or the like, which is used for providing electrical signals or electrical power to the pixels PX.

In an exemplary implementation, a sub-pixel PX may include a light-emitting device. The light-emitting device may include one of an organic light-emitting diode (OLED), a micro light-emitting diode (MLED) and a quantum dot light-emitting diode (QLED). The sub-pixel PX may emit light, such as red light, green light, blue light or white light, by the light-emitting device.

In an exemplary implementation, as shown in FIG. 1, the display panel includes the display area 100 having a rectangular shape. In some embodiments, the display area 100 may also be in a shape of a circle, an ellipse or a polygon such as a triangle, a pentagon, a hexagon or an octagon.

In an exemplary implementation, the display panel may be a flat display panel. In some embodiments, the display panel may also be other types of display panels, such as a flexible display panel, a foldable display panel, a rollable display panel, etc.

The light-emitting device in the display panel in accordance with this embodiment being an organic light-emitting diode (OLED) will be described as an example hereinafter, but the display panel in accordance with this embodiment is not limited thereto. In another embodiment, the light-emitting device in the display panel may be a micro light-emitting diode (MLED) or a quantum dot light-emitting diode (QLED). For example, a light-emitting layer of the light-emitting device in the display panel may include an organic material, an inorganic material, quantum dots, an organic material and quantum dots, an inorganic material and quantum dots, or an organic material, an inorganic material and quantum dots.

FIG. 2 is a first sectional view of a display panel in accordance with an embodiment of the present disclosure. FIG. 2 may be a sectional view taken along A-A′ direction in FIG. 1. FIG. 2 illustrates a sectional view of one first pixel PX1, one second sub-pixel PX2 and one third pixel PX3. In an exemplary implementation, the display panel in accordance with the embodiment of the present disclosure may include more pixels PX (see FIG. 1). Although the first to third pixels PX1 to PX3 are shown to be adjacent to each other in FIG. 2, the embodiment of the present disclosure is not limited thereto. That is to say, other components such as traces may be between the first pixel PX1 to the third pixel PX3. The first pixel PX1, the second sub-pixel PX2 and the third pixel PX3 may be pixels which are not adjacent to each other. In FIG. 2, cross sections of the first pixel PX1 to the third pixel PX3 may not be cross sections in a same direction on the display panel.

In an exemplary implementation, as shown in FIG. 2, the display panel in accordance with the embodiment of the present disclosure may include a light-emitting substrate 10, a light extraction structure layer 11 and a color conversion layer 12. The light extraction structure layer 11 is located between the light-emitting substrate 10 and the color conversion layer 12. The light-emitting substrate 10 may include a drive circuit and at least one light-emitting device connected to the drive circuit. The drive circuit may include a thin film transistor. The drive circuit is configured to provide a drive signal for the light-emitting device. The light-emitting device can emit light under driving of the drive circuit. The light-emitting device in the light-emitting substrate 10 is configured to provide incident light Lib to the light extraction structure layer 11. The light extraction structure layer 11 is configured to form at least a portion of the incident light Lib provided by the light-emitting substrate 10 into collimated light and emit the collimated light towards the color conversion layer 12. The color conversion layer 12 is configured to convert the collimated light into light of a specific color or to transmit the collimated light. The light-emitting device may be an organic light-emitting diode (OLED).

The display panel in accordance with the embodiment of the present disclosure forms the incident light Lib provided by the light-emitting substrate 10 into the collimated light through the light extraction structure layer 11, and then emits the collimated light towards the color conversion layer 12, thereby improving a light absorption efficiency of the color conversion layer 12 and further improving a display brightness of the display panel.

In the display panel in accordance with the embodiment of the present disclosure, the structure, refractive index parameters, etc., of the light extraction structure layer 11 can be adjusted to ensure the light extraction efficiency of the light-emitting substrate 10, for example, the shape, thickness, etc., of the light extraction structure layer 11 can be adjusted.

In an exemplary implementation, as shown in FIG. 2, the light-emitting substrate 10 includes a first light-emitting device 21, a second light-emitting device 22, a third light-emitting device 23 and a pixel definition layer 24, which is located at a periphery of the first light-emitting device 21, a periphery of the second light-emitting device 22 and a periphery of the third light-emitting device 23, respectively. The first light-emitting device 21 is located in the first pixel PX1, the second light-emitting device 22 is located in the second pixel PX2, and the third light-emitting device 23 is located in the third pixel PX3. The first light-emitting device 21, the second light-emitting device 22 and the third light-emitting device 23 may all be organic light-emitting diodes (OLEDs). The first light-emitting device 21, the second light-emitting device 22 and the third light-emitting device 23 may all emit blue light, and the pixel defining layer 24 is a non-light-emitting area.

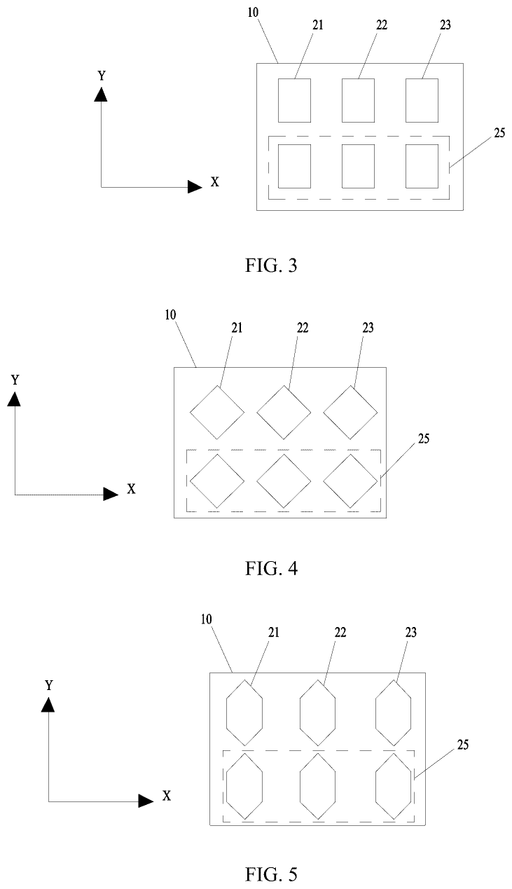

FIG. 3 is a first schematic diagram of a planar structure of a light-emitting substrate in a display panel in accordance with an embodiment of the present disclosure. In an exemplary implementation, as shown in FIG. 3, orthographic projections of the first light-emitting device 21, the second light-emitting device 22 and the third light-emitting device 23 on a plane where the display panel is located are each in a shape of a rectangle. The rectangle has a first side length and a second side length. A ratio of the first side length to the second side length of the rectangle can be adjusted according to different requirements for the pixels per inch (PPI) of the light-emitting substrate 10. For example, the ratio of the first side length to the second side length can be about 1 to 10, and the first side length can be about 10 μm to 80 μm. The first light-emitting device 21, the second light-emitting device 22 and the third light-emitting device 23 are sequentially arranged in the first direction X to form a row 25 of light-emitting devices, and multiple rows 25 of light-emitting devices are sequentially arranged in the second direction Y. The second side length is a side length in the first direction X of the rectangle, and the first side length is a side length in the second direction Y of the rectangle. The first direction X intersects the second direction Y. Exemplarily, the first direction X is perpendicular to the second direction Y.

FIG. 4 is a second schematic diagram of a planar structure of a light-emitting substrate in a display panel in accordance with an embodiment of the present disclosure. In an exemplary implementation, as shown in FIG. 4, orthographic projections of the first light-emitting device 21, the second light-emitting device 22 and the third light-emitting device 23 on the plane where the display panel is located are each in a shape of a rhombus. The rhombus has a first diagonal length and a second diagonal length. A ratio of the first diagonal length to the second diagonal length of the rhombus can be adjusted according to different requirements for the pixels per inch (PPI) of the light-emitting substrate 10. For example, the ratio of the first diagonal length to the second diagonal length can be about 1 to 10, and the first diagonal length can be about 10 μm to 80 μm. The first light-emitting device 21, the second light-emitting device 22 and the third light-emitting device 23 are sequentially arranged in the first direction X to form a row 25 of light-emitting devices, and multiple rows 25 of light-emitting devices are sequentially arranged in the second direction Y. The first diagonal length is a diagonal length in the first direction X of the rhombus, and the second diagonal length is a diagonal length in the second direction Y of the rhombus.

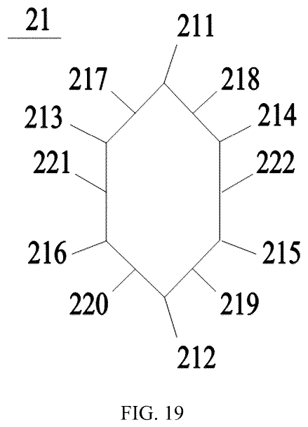

FIG. 5 is a third schematic diagram of a planar structure of a light-emitting substrate in a display panel in accordance with an embodiment of the present disclosure. FIG. 19 is a schematic diagram of a planar structure of a light-emitting device in a display panel in accordance with an embodiment of the present disclosure. In an exemplary implementation, as shown in FIGS. 5 and 19, the orthographic projections of the first light-emitting device 21, the second light-emitting device 22 and the third light-emitting device 23 on the plane where the display panel is located each all in the shape of a hexagon. Taking the first light-emitting device 21 as an example, the first light-emitting device 21 includes a first vertex angle 211 and a second vertex angle 212 diametrically opposed, a first side angle 213 and a second side angle 214 disposed at two sides of the first vertex angle 211, and a third side angle 215 and a fourth side angle 216 disposed at two sides of the second vertex angle 212 respectively. The first vertex angle 211 is about 60° to 120°, the second vertex angle 212 is about 60° to 120°, and the first side angle 213, the second side angle 214, the third side angle 215 and the fourth side angle 216 are all 120° to 150°. The first light-emitting device 21 further includes a first side 217 and a second side 218 which are both connected to the first vertex corner 211, a third side 219 and a fourth side 220 which are both connected to the second vertex corner 212, a fifth side 221 located between the first side 217 and the fourth side 220, and a sixth side 222 located between the second side 218 and the third side 219. The first side 217, the fourth side 220, the fifth side 221, the first side angle 213 and the fourth side angle 216 are located at a same side of the first vertex angle 211 and the second vertex angle 212, and the second side 218, the third side 219, the sixth side 222, the second side angle 214 and the third side angle 215 are located at a same side of the first vertex angle 211 and the second vertex angle 212. The first side 217 is parallel to the third side 219, the second side 218 is parallel to the fourth side 220, and the fifth side 221 is parallel to the sixth side 222. The first side 217, the second side 218, the third side 219 and the fourth side 220 are of a same length, and the fifth side 221 and the sixth side 222 are of a same length. The lengths of the first side 217, the second side 218, the third side 219, the fourth side 220, the fifth side 221 and the sixth side 222 can be adjusted according to according to different requirements for the pixels per inch (PPI) of the light-emitting substrate 10. For example, the lengths of the first side 217, the second side 218, the third side 219, the fourth side 220, the fifth side 221 and the sixth side 222 can be 10 μm to 120 μm.

In some embodiments, the orthographic projections of the first light-emitting device, the second light-emitting device and the third light-emitting device on the plane where the display panel may also be in a shape of another regular or irregular figure. For example, the orthographic projections of the first light-emitting device, the second light-emitting device and the third light-emitting device on the plane where the display panel is located may also be in a shape of a circle, a triangle, an octagon, a trapezoid, etc.

In some embodiments, the orthographic projections of the first light-emitting device, the second light-emitting device and the third light-emitting device on the plane where the display panel is located may have the same or different areas. For example, a light-emitting area of the first light-emitting device is greater than a light-emitting area of the second light-emitting device, and the light-emitting area of the second light-emitting device is greater than a light-emitting area of the third light-emitting device. As another example, the light-emitting area of the first light-emitting device is equal to the light-emitting area of the second light-emitting device and greater than the light-emitting area of the third light-emitting device.

In an exemplary implementation, as shown in FIG. 2, the display panel in accordance with the embodiment of the present disclosure further includes an encapsulation layer 13, and the encapsulation layer 13 is located between the light-emitting substrate 10 and the light extraction structure layer 11. The encapsulation layer 13 overlies the first light-emitting device 21, the second light-emitting device 22 and the third light-emitting device 23 to protect the first light-emitting device 21, the second light-emitting device 22 and the third light-emitting device 23 and prevent external moisture or oxygen from damaging the first light-emitting device 21, the second light-emitting device 22 and the third light-emitting device 23.

In an exemplary implementation, as shown in FIG. 2, the encapsulation layer 13 may include a first inorganic encapsulation layer 31, a second inorganic encapsulation layer 32 and an organic encapsulation layer 33 located between the first inorganic encapsulation layer 31 and the second inorganic encapsulation layer 32. The first inorganic encapsulation layer 31 and the second inorganic encapsulation layer 32 may each include one or more inorganic insulating materials. The inorganic insulating material may include one of aluminum oxide, titanium oxide, tantalum oxide, hafnium oxide, zinc oxide, silicon oxide, silicon nitride and/or silicon oxynitride. The first inorganic encapsulation layer 31 and the second inorganic encapsulation layer 32 may be formed by chemical vapor deposition. The organic encapsulation layer 33 may be made of a polymer material. The polymer material may include one of acrylic resin, epoxy resin, polyimide and polyethylene.

In an exemplary implementation, the first light-emitting device 21 may provide incident light Lib incident on the first color conversion pattern 51 which will be described in more detail later, the second light-emitting device 22 may provide incident light Lib incident on the second color conversion pattern 52 which will be described in more detail later, and the third light-emitting device 23 may provide incident light Lib incident on the light transmission pattern 53 which will be described in more detail later. The incident light Lib emitted from the first light-emitting device 21, the second light-emitting device 22 and the third light-emitting device 23 may pass through the encapsulation layer 13 and enter the first color conversion pattern 51, the second color conversion pattern 52 and the light transmission pattern 53.

In an exemplary implementation, as shown in FIG. 2, the light extraction structure layer 11 includes at least one light extraction pattern. An orthographic projection of the light extraction pattern on the plane where the display panel is located overlaps at least partially with an orthographic projection of the light-emitting device on the plane where the display panel is located. For example, the light extraction pattern and the light-emitting device in the light-emitting substrate 10 are in one-to-one correspondence. The orthographic projection of the light extraction pattern on the plane where the display panel is located coincides with the orthographic projection of its corresponding light-emitting device on the plane where the display panel is located, such that the incident light Lib provided by the light-emitting substrate 10 can enter the light extraction pattern, which is configured to form the incident light Lib into collimated light and emit the collimated light towards the color conversion layer 12, that is, after the incident light Lib provided by the light-emitting substrate 10 is formed into the collimated light in the light extraction structure layer 11, it is directed towards the color conversion layer 12.

In an exemplary implementation, as shown in FIG. 2, one light extraction pattern includes multiple protrusions 44, and the protrusions 44 extend along a direction away from the light-emitting substrate 10. The multiple protrusions 44 makes a surface of the light extraction structure layer 11 away from the light-emitting substrate 10 uneven. At least two protrusions in one light extraction pattern are of different sizes. For example, the at least two protrusions in the light extraction pattern are of different heights; and/or orthographic projections of the at least two protrusions in the light extraction pattern on the plane where the display panel is located have different areas. A height of a protrusion 44 is a maximum distance of the protrusion 44 from its bottom in a third direction Z, wherein the third direction Z intersects the first direction X and the second direction Y. For example, the third direction Z is perpendicular to the first direction X and the second direction Y respectively.

In some embodiments, protrusions in one light extraction pattern may be of a same size, which will not be repeated herein in the embodiment of the present disclosure.

In the display panel in accordance with the embodiment of the present disclosure, the sizes of the protrusions in the light extraction pattern can be adjusted for different light-emitting devices, so that the light extraction pattern can be more adaptable to its corresponding light-emitting device, to improve a light extraction efficiency of the light-emitting device.

In an exemplary implementation, the protrusions 44 may be in various shapes. For example, a shape of the protrusions 44 may include at least one of at least one of cone, hemisphere or pyramid. The protrusions 44 may be made of an organic material. For example, the protrusions 44 may be made of an acrylic resin, a polyurethane resin, a silicone resin or an epoxy resin. A refractive index of the protrusions 44 may be about 1 to 2. For example, the refractive index of the protrusions 44 may be about 1.3 to 1.5.

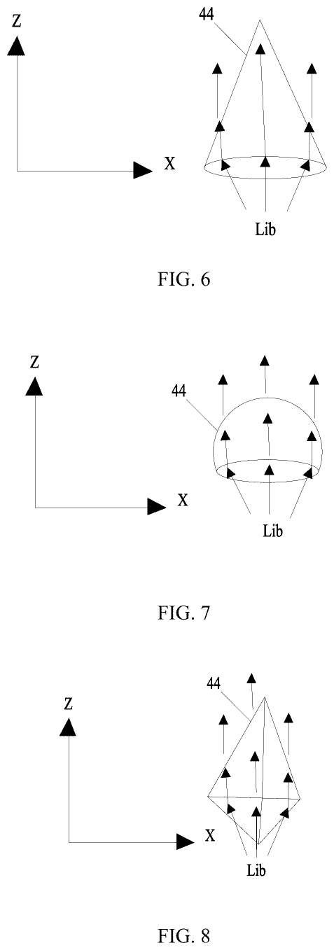

FIG. 6 is a first schematic structural diagram of a protrusion in a display panel in accordance with an embodiment of the present disclosure. In an exemplary implementation, as shown in FIG. 6, the protrusion 44 is in a shape of a cone. A surface of the protrusion 44 close to the light-emitting substrate is in the shape of a circle. After the incident light Lib provided by the light-emitting devices in the light-emitting substrate 10 enters the protrusion 44 from the surface of the protrusion 44 close to the light-emitting substrate, the incident light Lib is refracted in the protrusion 44, so that the incident light Lib is formed into the collimated light and is emitted.

FIG. 7 is a second schematic structural diagram of a protrusion in a display panel in accordance with an embodiment of the present disclosure. In an exemplary implementation, as shown in FIG. 7, the protrusion 44 is in a shape of a hemisphere. A surface of the protrusion 44 close to the light-emitting substrate is in the shape of a circle. After the incident light Lib provided by the light-emitting devices in the light-emitting substrate 10 enters the protrusion 44 from the surface of the protrusion 44 close to the light-emitting substrate, the incident light Lib is refracted in the protrusion 44, so that the incident light Lib is formed into the collimated light and is emitted.

FIG. 8 a third schematic structural diagram of a protrusion in a display panel in accordance with an embodiment of the present disclosure. In an exemplary implementation, as shown in FIG. 8, the protrusion 44 is in a shape of a pyramid. A surface of the protrusion 44 close to the light-emitting substrate is in the shape of an equilateral triangle. After the incident light Lib provided by the light-emitting device in the light-emitting substrate 10 enters the protrusion 44 from the surface of the protrusion 44 close to the light-emitting substrate, the incident light Lib is refracted in the protrusion 44, so that the incident light Lib is formed into the collimated light and is emitted.

In an exemplary implementation, the multiple protrusions in the light extraction pattern are arranged in a shape of at least one of a rectangle, a hexagon, a circle, a rhombus, a triangle and a trapezoid. In the display panel in accordance with the embodiment of the present disclosure, for light-emitting devices of different shapes, light extraction patterns in different arrangements can be used, so as to improve the light extraction efficiency of the light-emitting devices. For example, if the orthographic projection of the light-emitting device on the plane where the display panel is located is in the shape of a rectangle, the multiple protrusions in its corresponding light extraction pattern are arranged in the shape of a rectangle.

In an exemplary implementation, as shown in FIG. 2, the light extraction structure layer 11 includes a first light extraction pattern 41, a second light extraction pattern 42 and a third light extraction pattern 43. An orthographic projection of the first light extraction pattern 41 on the plane where the display panel is located overlaps at least partially with the orthographic projection of the first light-emitting device 21 on the plane where the display panel is located. For example, the orthographic projection of the first light extraction pattern 41 on the plane where the display panel is located coincides with the orthographic projection of the first light-emitting device 21 on the plane where the display panel is located. The incident light Lib provided by the first light-emitting device 21 enters the first light extraction pattern 41, and the first light extraction pattern 41 is configured to form the incident light Lib into collimated light and emit the collimated light towards the first color conversion pattern 51 which will be described in more detail later. An orthographic projection of the second light extraction pattern 42 on the plane where the display panel is located overlaps at least partially with the orthographic projection of the second light-emitting device 22 on the plane where the display panel is located. For example, the orthographic projection of the second light extraction pattern 42 on the plane where the display panel is located coincides with the orthographic projection of the second light-emitting device 22 on the plane where the display panel is located. The incident light Lib provided by the second light-emitting device 22 enters the second light extraction pattern 42, and the second light extraction pattern 42 is configured to form the incident light Lib into collimated light and emit the collimated light towards the second color conversion pattern 52 which will be described in more detail later. An orthographic projection of the third light extraction pattern 43 on the plane where the display panel is located overlaps at least partially with the orthographic projection of the third light-emitting device 23 on the plane where the display panel is located. For example, the orthographic projection of the third light extraction pattern 43 on the plane where the display panel is located coincides with the orthographic projection of the third light-emitting device 23 on the plane where the display panel is located. The incident light Lib provided by the third light-emitting device 23 enters the third light extraction pattern 43, and the third light extraction pattern 43 is configured to form the incident light Lib into collimated light and emit the collimated light towards the third color conversion pattern 53 which will be described in more detail later.

In the display panel in accordance with the embodiment of the present disclosure, for light-emitting devices of different shapes, light extraction patterns of different shapes can be used, to improve the light extraction efficiency of the light-emitting devices. For example, for the light-emitting devices of different shapes, the light extraction patterns with protrusions of different or the same shape and/or size are used.

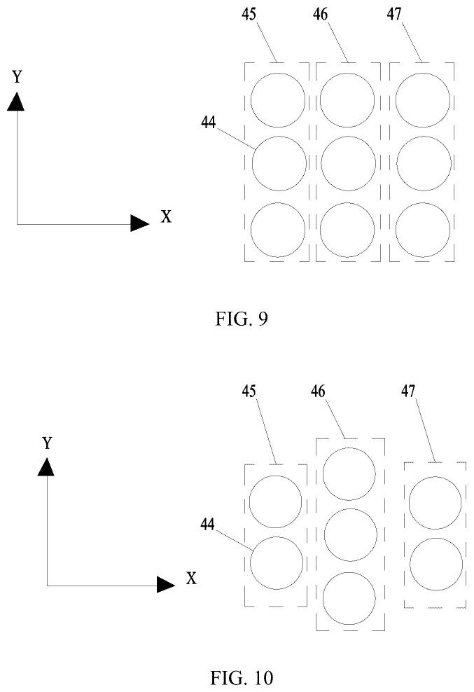

FIG. 9 is a first schematic diagram of a planar structure of a light extraction pattern in a display panel in accordance with an embodiment of the present disclosure. In the exemplary embodiment, as shown in FIG. 9, an orthographic projection of a light-emitting device on the plane where the display panel is located is in the shape of a rectangle, and the protrusions 44 in its corresponding light extraction pattern are arranged in the shape of a rectangle. A part of the protrusions 44 in the light extraction pattern are arranged along the second direction Y to form a first column 45 of protrusions, a second column 46 of protrusions and a third column 47 of protrusions. The first column 45 of protrusions, the second column 46 of protrusions and the third column 47 of protrusions are arranged in sequence along the first direction X. The protrusions 44 in the first column 45 of protrusions may be of the same shape and size, the protrusions 44 in the second column 46 of protrusions may be of the same shape and size, and the protrusions 44 in the third column 47 of protrusions may be of the same shape and size. The shape and size of the protrusions 44 in the first column 45 of protrusions may be the same as or different from the shape and size of the protrusions 44 in the second column 46 of protrusions, the shape and size of the protrusions 44 in the second column 46 of protrusions may be the same as or different from the shape and size of the protrusions 44 in the third column 47 of protrusions, and the shape and size of the protrusions 44 in the third column 47 of protrusions may be the same as or different from the shape and size of the protrusions 44 in the first column 45 of protrusions.

In an exemplary implementation, the protrusions 44 in the light extraction pattern may be in the shape of a cone, wherein a ratio of a bottom radius of the cone to a height of the cone is about 0.5 to 1, and the bottom radius of the cone may be about 10 microns to 60 microns; and/or the protrusions 44 in the light extraction pattern may be in the shape of a hemisphere, wherein a ratio of a bottom radius of the hemisphere to a height of the hemisphere is about 0.8 to 1, and the bottom radius of the hemisphere may be about 10 microns to 60 microns; and/or the protrusions 44 in the light extraction pattern may be in the shape of a pyramid, a bottom surface of the pyramid is in the shape of an equilateral triangle, wherein a ratio of a distance between the center and an edge to a height of the pyramid is about 0.5 to 1.0, and the distance between the center and the edge may be about 10 microns to 40 microns.

FIG. 10 is a second schematic diagram of a planar structure of a light extraction pattern in a display panel in accordance with an embodiment of the present disclosure. In the exemplary embodiment, as shown in FIG. 10, an orthographic projection of a light-emitting device on the plane where the display panel is located is in the shape of a rhombus, and the protrusions 44 in its corresponding light extraction pattern are arranged in the shape of a hexagon. A part of the protrusions 44 in the light extraction pattern are arranged along the second direction Y to form a first column 45 of protrusions, a second column 46 of protrusions and a third column 47 of protrusions. The first column 45 of protrusions, the second column 46 of protrusions and the third column 47 of protrusions are arranged in sequence along the first direction X. A length of the first column 45 of protrusions in the second direction Y is the same as a length of the third column 47 of protrusions in the second direction Y, and a length of the second column 46 of protrusions in the second direction Y is greater than the length of the first column 45 of protrusions in the second direction Y. The protrusions 44 in the first column 45 of protrusions may be of the same shape and size, the protrusions 44 in the second column 46 of protrusions may be of the same shape and size, and the protrusions 44 in the third column 47 of protrusions may be of the same shape and size. The shape and/or size of the protrusions 44 in the first column 45 of protrusions may be the same as or different from the shape and/or size of the protrusions 44 in the second column 46 of protrusions, the shape and/or size of the protrusions 44 in the second column 46 of protrusions may be the same as or different from the shape and/or size of the protrusions 44 in the third column 47 of protrusions, and the shape and/or size of the protrusions 44 in the first column 45 of protrusions may be the same as or different from the shape and size of the protrusions 44 in the third column 47 of protrusions.

In an exemplary implementation, each of the protrusions 44 in the first column 45 of protrusions, each of the protrusions 44 in the second column 46 of protrusions and each of the protrusions 44 in the third column 47 of protrusions are all in the shape of a cone. Each of the protrusions 44 in the first column 45 of protrusions and each of the protrusions 44 in the third column 47 of protrusions are of a same size. A height of each of the protrusions 44 in the second column 46 of protrusions is greater than or less than a height of each of the protrusions 44 in the first column 45 of protrusions. Specifically, a ratio of a bottom radius to a height of each of the protrusions 44 in the first column 45 and the third column 47 of protrusions is about 0.5 to 1, and the bottom radius of the protrusion 44 may be about 20 microns to 40 microns, with a boundary value of 20 microns to 40 microns exclusive in the bottom radius of the protrusion 44, for example, the bottom radius of the protrusion 44 is not 20 microns or 40 microns. The ratio of the bottom radius to the height of each of the protrusions 44 in the second column 46 of protrusions is about 0.5 to 1, and the bottom radius of the protrusion 44 may be about 10 microns to 20 microns or 40 microns to 60 microns, with a boundary value of 10 microns to 20 microns or 40 microns to 60 microns inclusive in the bottom radius of the protrusion 44, for example, the bottom radius of the protrusion 44 may be 10 microns, 20 microns, 40 microns or 60 microns. The bottom surface of the protrusion 44 is a surface of the protrusion 44 close to the light-emitting substrate.

In an exemplary implementation, each of the protrusions 44 in the first column 45 of protrusions, each of the protrusions 44 in the second column 46 of protrusions and each of the protrusions 44 in the third column 47 of protrusions are all in the shape of a hemisphere. Each of the protrusions 44 in the first column 45 of protrusions and each of the protrusions 44 in the third column 47 of protrusions are of a same size. A height of each of the protrusions 44 in the second column 46 of protrusions is greater than or less than a height of each of the protrusions 44 in the first column 45 of protrusions. Specifically, a ratio of a bottom radius to a height of each of the protrusions 44 in the first column 45 and the third column 47 of protrusions is about 0.8 to 1, and the bottom radius of the protrusion 44 may be about 20 microns to 40 microns, with a boundary value of 20 microns to 40 microns exclusive in the bottom radius of the protrusion 44, for example, the bottom radius of the protrusion 44 is not 20 microns or 40 microns. A ratio of the bottom radius to the height of each of the protrusions 44 in the second column 46 of protrusions is about 0.8 to 1, and the bottom radius of the protrusion 44 may be about 10 microns to 20 microns or 40 microns to 60 microns, with a boundary value of 10 microns to 20 microns or 40 microns to 60 microns inclusive in the bottom radius of the protrusion 44, for example, the bottom radius of the protrusion 44 may be 10 microns, 20 microns, 40 microns or 60 microns.

In an exemplary implementation, each of the protrusions 44 in the first column 45 of protrusions, each of the protrusions 44 in the second column 46 of protrusions and each of the protrusions 44 in the third column 47 of protrusions are in the shape of a pyramid, the bottom surface of the pyramid is in the shape of an equilateral triangle. Each of the protrusions 44 in the first column 45 of protrusions and each of the protrusions 44 in the third column 47 of protrusions are of a same size. A height of each of the protrusions 44 in the second column 46 of protrusions is greater than or less than a height of each of the protrusions 44 in the first column 45 of protrusions. Specifically, a ratio of a distance between a bottom center and a bottom edge to the height of each of the protrusions 44 in the first column 45 and the third column 47 of protrusions is about 0.5 to 1.0, and the distance between the bottom center and the bottom edge of the protrusion 44 may be about 20 microns to 30 microns, with a boundary value of 20 microns to 30 microns exclusive in a bottom radius of the protrusion 44, for example, the bottom radius of the protrusion 44 is not 20 microns or 30 microns. A ratio of a distance between a bottom center and a bottom edge to the height of each of the protrusions 44 in the second column 46 of protrusions is about 0.5 to 1.0, and the distance between the bottom center and the bottom edge of the protrusion 44 may be about 10 microns to 20 microns or 30 microns to 40 microns, with a boundary value of 10 microns to 20 microns or 30 microns to 40 microns inclusive in a bottom radius of the protrusion 44, for example, the bottom radius of the protrusion 44 may be 10 microns, 20 microns, 30 microns or 40 microns.

In an exemplary implementation, each of the protrusions 44 in the first column 45 of protrusions and each of the protrusions 44 in the third column 47 of protrusions are of a same shape, i.e., in the shape of a hemisphere. A ratio of a bottom radius to the height of each of the protrusions 44 in the first column 45 and the third column 47 of protrusions is about 0.8 to 1, and the bottom radius of the protrusion 44 may be about 10 microns to 40 microns. Each of the protrusions 44 in the second column 46 of protrusions and each of the protrusions 44 in the first column 45 of protrusions are of different shapes, and each of the protrusions 44 in the second column 46 of protrusions is in the shape of a cone. A ratio of a bottom radius to the height of each of the protrusions 44 in the second column 46 of protrusions is about 0.5 to 1, and the bottom radius of the protrusion 44 may be about 10 microns to 40 microns. Alternatively, each of the protrusions 44 in the second column 46 of protrusions is in the shape of a pyramid, the bottom surface of the pyramid is in the shape of a equilateral triangle, a distance between a bottom center and a bottom edge to the height of the protrusion 44 is about 0.5 to 1.0, and the distance between the bottom center and the bottom edge of the protrusion 44 may be about 10 microns to 30 microns.

In an exemplary implementation, an orthographic projection of a light-emitting device on the plane where the display panel is located is in the shape of a hexagon, and the protrusions 44 in its corresponding light extraction pattern are arranged in the shape of a hexagon, as shown in FIG. 10. A part of the protrusions 44 in the light extraction pattern are arranged along the second direction Y to form a first column 45 of protrusions, a second column 46 of protrusions and a third column 47 of protrusions. The first column 45 of protrusions, the second column 46 of protrusions and the third column 47 of protrusions are arranged in sequence along the first direction X. A length of the first column 45 of protrusions in the second direction Y is the same as a length of the third column 47 of protrusions in the second direction Y, and a length of the second column 46 of protrusions in the second direction Y is greater than the length of the first column 45 of protrusions in the second direction Y. The protrusions 44 in the first column 45 of protrusions may be of a same shape and size, the protrusions 44 in the second column 46 of protrusions may be of a same shape and size, and the protrusions 44 in the third column 47 of protrusions may be of a same shape and size. The shape and/or size of the protrusions 44 in the first column 45 of protrusions may be the same as or different from the shape and/or size of the protrusions 44 in the second column 46 of protrusions, the shape and/or size of the protrusions 44 in the second column 46 of protrusions may be the same as or different from the shape and/or size of the protrusions 44 in the third column 47 of protrusions, and the shape and/or size of the protrusions 44 in the first column 45 of protrusions may be the same as or different from the shape and size of the protrusions 44 in the third column 47 of protrusions.

In an exemplary implementation, each of the protrusions 44 in the first column 45 of protrusions, each of the protrusions 44 in the second column 46 of protrusions and each of the protrusions 44 in the third column 47 of protrusions are all in the shape of a cone. Each of the protrusions 44 in the first column 45 of protrusions and each of the protrusions 44 in the third column 47 of protrusions are of a same size. A height of each of the protrusions 44 in the second column 46 of protrusions is greater than or less than a height of each of the protrusions 44 in the first column 45 of protrusions. Specifically, a ratio of a bottom radius to the height of each of the protrusions 44 in the first column 45 of protrusions and the third column 47 of protrusions is about 0.8 to 1, and the bottom radius of the protrusion 44 may be about 20 microns to 40 microns, with a boundary value of 20 microns to 40 microns exclusive in the bottom radius of the protrusion 44, for example, the bottom radius of the protrusion 44 is not 20 microns or 40 microns. A ratio of a bottom radius to the height of each of the protrusions 44 in the second column 46 of protrusions is about 0.8 to 1, and the bottom radius of the protrusion 44 may be about 10 microns to 20 microns or 40 microns to 60 microns, with a boundary value of 10 microns to 20 microns or 40 microns to 60 microns inclusive in the bottom radius of the protrusion 44, for example, the bottom radius of the protrusion 44 may be 10 microns, 20 microns, 40 microns or 60 microns.

In an exemplary implementation, each of the protrusions 44 in the first column 45 of protrusions, each of the protrusions 44 in the second column 46 of protrusions and each of the protrusions 44 in the third column 47 of protrusions are in the shape of a hemisphere. Each of the protrusions 44 in the first column 45 of protrusions and each of the protrusions 44 in the third column 47 of protrusions are of a same size. A height of each of the protrusions 44 in the second column 46 of protrusions is greater than or less than a height of each of the protrusions 44 in the first column 45 of protrusions. Specifically, a ratio of a bottom radius to the height of each of the protrusions 44 in the first column 45 of protrusions and the third column 47 of protrusions is about 0.8 to 1, and the bottom radius of the protrusion 44 may be about 20 microns to 40 microns, with a boundary value of 20 microns to 40 microns exclusive in the bottom radius of the protrusion 44, for example, the bottom radius of the protrusion 44 is not 20 microns or 40 microns. A ratio of the bottom radius to the height of each of the protrusions 44 in the second column 46 of protrusions is about 0.8 to 1, and the bottom radius of the protrusion 44 may be about 10 microns to 20 microns or 40 microns to 60 microns, with a boundary value of 10 microns to 20 microns or 40 microns to 60 microns inclusive in the bottom radius of the protrusion 44, for example, the bottom radius of the protrusion 44 may be 10 microns, 20 microns, 40 microns or 60 microns.

In an exemplary implementation, each of the protrusions 44 in the first column 45 of protrusions, each of the protrusions 44 in the second column 46 of protrusions and each of the protrusions 44 in the third column 47 of protrusions are in the shape of a pyramid, the bottom surface of the pyramid is in the shape of an equilateral triangle. Each of the protrusions 44 in the first column 45 of protrusions and each of the protrusions 44 in the third column 47 of protrusions are of a same size. A height of each of the protrusions 44 in the second column 46 of protrusions is greater than or less than a height of each of the protrusions 44 in the first column 45 of protrusions. Specifically, a ratio of a distance between a bottom center and a bottom edge to the height of each of the protrusions 44 in the first column 45 and the third column 47 of protrusions is about 0.6 to 1.0, and the distance between the bottom center and the bottom edge of the protrusion 44 may be about 15 microns to 30 microns, with a boundary value of 15 microns to 30 microns exclusive in the bottom radius of the protrusion 44, for example, the bottom radius of the protrusion 44 is not 15 microns or 30 microns. A ratio of a distance between a bottom center and a bottom edge to the height of each of the protrusions 44 in the second column 46 of protrusions is about 0.6 to 1.0, and the distance between the bottom center and the bottom edge of the protrusion 44 may be about 10 microns to 20 microns or 40 microns to 60 microns, with a boundary value of 10 microns to 20 microns or 40 microns to 60 microns inclusive in the bottom radius of the protrusion 44, for example, the bottom radius of the protrusion 44 may be 10 microns, 20 microns, 40 microns or 60 microns.

In an exemplary implementation, each of the protrusions 44 in the first column 45 of protrusions and each of the protrusions 44 in the third column 47 of protrusions are of a same shape and size, i.e., in the shape of a hemisphere. A ratio of a bottom radius to a height of each of the protrusions 44 in the first column 45 of protrusions and the third column 47 of protrusions is about 0.8 to 1, and the bottom radius of the protrusion 44 may be about 20 microns to 40 microns, with a boundary value of 20 microns to 40 microns inclusive in the bottom radius of the protrusion 44, for example, the bottom radius of the protrusion 44 may be 20 microns or 40 microns. The protrusions 44 in the second column 46 of protrusions and the protrusions 44 in the first column 45 of protrusions are of different shapes, and each of the protrusions 44 in the second column 46 of protrusions is in the shape of a cone. A ratio of the bottom radius to the height of each of the protrusions 44 in the second column 46 of protrusions is about 0.8 to 1, and the bottom radius of the protrusion 44 may be about 20 microns to 40 microns, with a boundary value of 20 microns to 40 microns inclusive in the bottom radius of the protrusion 44, for example, the bottom radius of the protrusion 44 may be 20 microns or 40 microns. Alternatively, each of the protrusions 44 in the second column 46 of protrusions is in the shape of a pyramid, the bottom surface of the pyramid is in the shape of an equilateral triangle, a distance between a bottom center and a bottom edge of the protrusion 44 to the height of the protrusion 44 is about 0.6 to 1.0, and the distance between the bottom center and the bottom edge of the protrusion 44 may be 15 microns to 30 microns, with a boundary values of 15 microns to 30 microns inclusive in the bottom radius of the protrusion 44, for example, the bottom radius of the protrusion 44 may be 15 microns or 30 microns.

In an exemplary implementation, as shown in FIG. 2, the color conversion layer 12 includes a first color conversion pattern 51, a second color conversion pattern 52, a light transmission pattern 53 and a light blocking pattern 54. The light blocking pattern 54 is located at a periphery of the first color conversion pattern 51, a periphery of the second color conversion pattern 52 and a periphery of the light transmission pattern 53. An orthographic projection of the first color conversion pattern 51 on the plane where the display panel is located overlaps at least partially with an orthographic projection of the first light-emitting device 21 on the plane where the display panel is located. For example, the orthographic projection of the first color conversion pattern 51 on the plane where the display panel is located coincides with the orthographic projection of the first light-emitting device 21 on the plane where the display panel is located. An orthographic projection of the second color conversion pattern 52 on the plane where the display panel is located overlaps at least partially with an orthographic projection of the second light-emitting device 22 on the plane where the display panel is located. For example, the orthographic projection of the second color conversion pattern 52 on the plane where the display panel is located coincides with the orthographic projection of the second light-emitting device 22 on the plane where the display panel is located. An orthographic projection of the light transmission pattern 53 on the plane where the display panel is located overlaps at least partially with the orthographic projection of the third light-emitting device 23 on the plane where the display panel is located. For example, the orthographic projection of the light transmission pattern 53 on the plane where the display panel is located coincides with the orthographic projection of the third light-emitting device 23 on the plane where the display panel is located.

In an exemplary implementation, the light blocking pattern 54 may be in various colors, including black or white. For example, the light blocking pattern 54 may be black and may include a black matrix. The light blocking pattern 54 may be made of a light blocking material, which may include an opaque inorganic insulating material (e.g., chromium oxide or molybdenum oxide) or an opaque organic insulating material (e.g., black resin). As another example, the light blocking pattern 54 may include an organic insulating material such as a white resin.

In an exemplary implementation, the light blocking pattern 54 may prevent color blending between light beams converted or transmitted in the first color conversion pattern 51, the second color conversion pattern 52 and the light transmission pattern 53 which are adjacent to each other.

In an exemplary implementation, the first color conversion pattern 51 may convert blue incident light Lib provided by the first light-emitting device into red light Lr. The first color conversion pattern 51 may include a first photosensitive polymer with first quantum dots dispersed therein. The first photosensitive polymer may be an organic material, such as polysiloxane resin and epoxy resin, which has light transmission properties. The first quantum dots are excited by the blue incident light Lib to isotropically emit the red light Lr with a wavelength longer than that of the blue light. The first quantum dots may include a Group II-VI compound, a Group III-V compound, a Group IV-VI compound, a Group IV compound or a combination thereof.

In an exemplary implementation, the second color conversion pattern 52 may convert blue incident light Lib provided by the second light-emitting device into green light Lg. The second color conversion pattern 52 may include a second photosensitive polymer with second quantum dots dispersed therein. The second photosensitive polymer may be the same material as the first photosensitive polymer. The second quantum dots may include a Group II-VI compound, a Group III-V compound, a Group IV-VI compound, a Group IV compound or a combination thereof. A size of a second quantum dot may be smaller than that of a first quantum dot, the second quantum dots may be excited by the blue incident light Lib and emit light with a wavelength greater than that of the blue light, and may isotropically emit the green light Lg with a wavelength less than that of the red light Lr.

In an exemplary implementation, the light transmission pattern 53 may transmit blue incident light Lib provided by the third light-emitting device. The light transmission pattern 53 may be made of a third photosensitive polymer with scattering particles dispersed therein. The light transmission pattern 53 does not include individual quantum dots that can be excited by the blue incident light Lib. The third photosensitive polymer may include an organic material with light transmission properties, and the scattering particles may include titanium oxide particles or metal particles. The blue incident light Lib incident on the light transmission pattern 53 may be transmitted through the light transmission pattern 53 without color change, and the light emitted through the light transmission pattern 53 may be blue light Lb. The light transmission pattern 53 can transmits blue incident light Lib without changing its color, so as to obtain higher light efficiency.

In an exemplary implementation, the embodiment of the present disclosure further includes a color film substrate 14. The color film substrate 14 is located on one side of the color conversion layer 12 away from the light-emitting substrate 10. The first color conversion pattern 51, the second color conversion pattern 52 and the light transmission pattern 53 may convert the incident light Lib provided by the light-emitting substrate 10 into light of specific color or transmit the incident light Lib, and may emit the color-converted light or transmitted light towards the color film substrate. The color film substrate 14 can further absorb the incident light Lib provided by the light-emitting substrate to improve a light extraction rate of the display panel.

Most of the light emitted from the light extraction structure layer 11 in the display panel in accordance with the present disclosure will strike the color conversion layer 12 to be converted into light of a specific color or to be transmitted. However, light with wide viewing angle emitted from the light extraction structure layer 11 will be directed towards the light blocking pattern 54 in the color conversion layer 12, causing loss of light.

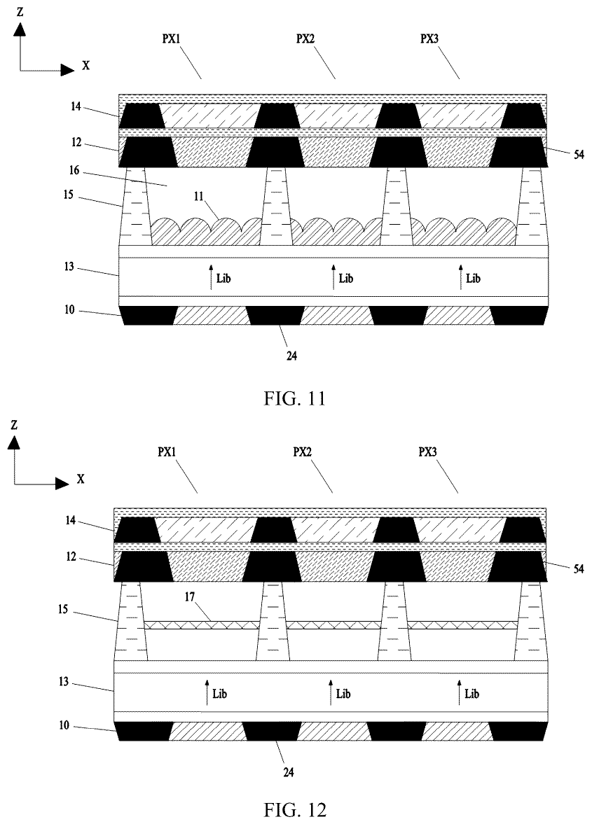

FIG. 11 is a second sectional view of a display panel in accordance with an embodiment of the present disclosure. In an exemplary implementation, as shown in FIG. 11, the display panel in accordance with the embodiment of the present disclosure further includes spacer posts 15 disposed between the light-emitting substrate 10 and the color conversion layer 12. One end of each spacer post 15 in the second direction Y is in contact with a surface of the encapsulation layer 13 on the light-emitting substrate 10 away from the light-emitting substrate 10, and the other end of the spacer post 15 in the second direction Y is in contact with a surface of the color conversion layer 12 close to the light-emitting substrate 10. The light extraction structure layer 11 is partitioned by the spacer posts 15 in the first direction X, so that a portion of the light extraction structure layer 11 is located between adjacent spacer posts 15 in the first direction X. The light with wide viewing angle emitted from the light extraction structure layer 11 is directed towards the spacer posts 15, and the spacer posts 15 are configured to reflect at least a portion of the light directed towards the spacer posts 15 towards the color conversion layer 12, thereby improving a light absorption rate and a conversion rate of the color conversion layer 12. The spacer posts 15 can be manufactured using a photolithography process.

In an exemplary implementation, as shown in FIG. 11, an orthographic projection of the spacer posts 15 on the plane where the display panel is located overlaps at least partially with an orthographic projection of the light blocking pattern 54 in the color conversion layer 12 on the plane where the display panel is located. For example, the orthographic projection of the spacer posts 15 on the plane where the display panel is located coincides with the orthographic projection of the light blocking pattern 54 in the color conversion layer 12 on the plane where the display panel is located, so as to prevent the spacer posts 15 from blocking a path of the light emitted from the light extraction structure layer 11 directly entering the color conversion layer 12.

In an exemplary implementation, as shown in FIG. 11, the orthographic projection of the spacer posts 15 on the plane where the display panel is located overlaps at least partially with an orthographic projection of a pixel definition layer 24 in the light-emitting substrate 10 on the plane where the display panel is located. For example, the orthographic projection of the spacer posts 15 on the plane where the display panel is located coincides with the orthographic projection of the pixel definition layer 24 in the light-emitting substrate 10 on the plane where the display panel is located.

In an exemplary implementation, a cross section of each spacer post in a plane perpendicular to a plane where the light-emitting substrate is located may be in various shapes. For example, the cross section of the spacer post in the plane perpendicular to the plane where the light-emitting substrate is located may be in the shape of a regular trapezoid or an inverted trapezoid. A thickness of the spacer posts may be about 20 microns to 60 microns. The thickness of the spacer posts may be their length in the second direction Y.

In an exemplary implementation, multiple spacer posts 15 are disposed at intervals along the first direction X, and a portion of the light extraction structure layer 11 is disposed between adjacent spacer posts 15, that is, the light extraction structure layer 11 is partitioned by the spacer posts 15 in the first direction X. The spacer posts 15 have side walls. Side walls of adjacent spacer posts 15, along with the portion of light extraction structure layer 11 and the color conversion layer 12, form closed chambers 16. A refractive index of the spacer posts 15 is less than a refractive index of a medium in the closed chambers 16. The refractive index of the spacer posts 15 may be about 1.8 to 2.0. The medium in the closed chambers 16 may be air or other fillers.

The light with wide viewing angle emitted from the light extraction structure layer 11 in the display panel in accordance with the embodiment of the present disclosure passes through the closed chambers 16 and is directed towards the spacer posts 15, the light with wide viewing angle is directed towards a low refractive index material (spacer posts 15) from a high refractive index material (the medium in the closed chambers 16), and the light with wide viewing angle will be totally reflected on the side walls of the spacer posts 15, so as to change an optical path of the light with wide viewing angle and emit the light with wide viewing angle towards the color conversion layer 12, to improve the light absorption rate and the conversion rate of the color conversion layer 12.

FIG. 12 is a third sectional view of a display panel in accordance with an embodiment of the present disclosure. In an exemplary implementation, as shown in FIG. 12, the display panel in accordance with the embodiment of the present disclosure further includes a light dispersion layer 17 disposed between the light-emitting substrate 10 and the color conversion layer 12. The incident light Lib provided by the light-emitting substrate 10 passes through the light dispersion layer 17 and is directed towards the color conversion layer 12. The light dispersion layer 17 is configured to scatter at least a portion of the incident light Lib directed towards the light dispersion layer 17 to form emergent light with uniform intensity and emit the emergent light towards the color conversion layer 12, thereby improving a excitation probability of quantum dot particles in the color conversion layer 12 and improving the light absorption rate and the conversion rate of the color conversion layer 12. A thickness of the light dispersion layer may be about 5 microns to 30 microns, for example, the thickness of the light dispersion layer may be about 10 microns to 20 microns. A refractive index of the light dispersion layer may be about 1 to 2, and the refractive index of the light dispersion layer may be about 1.4 to 1.6.

In an exemplary implementation, the light dispersion layer 17 is partitioned by the spacer posts 15 in the first direction X. An orthographic projection of the light dispersion layer 17 on the plane where the display panel is located overlaps at least partially with an orthographic projection of a light-emitting device in the light-emitting substrate 10 on the plane where the display panel is located. For example, the orthographic projection of the light dispersion layer 17 on the plane where the display panel is located coincides with the orthographic projection of the light-emitting device in the light-emitting substrate 10 on the plane where the display panel is located.

In an exemplary implementation, the light dispersion layer 17 may be disposed between the first color conversion pattern in the color conversion layer 12 and the first light-emitting device in the light-emitting substrate 10, between the second color conversion pattern in the color conversion layer 12 and the second light-emitting device in the light-emitting substrate 10, and between the light transmission pattern in the color conversion layer 12 and the third light-emitting device in the light-emitting substrate 10.

In an exemplary implementation, the light dispersion layer 17 may be located on one side of the light extraction structure layer close to the light-emitting substrate 10, or the light dispersion layer 17 may be located on one side of the light extraction structure layer away from the light-emitting substrate 10.

In an exemplary implementation, the light dispersion layer 17 includes a first matrix and additive particles disposed in the first matrix. The first matrix may be made of an organic material, for example, the first matrix may include one of or a combination of acrylic resin, polyurethane resin, silicone resin, silane resin and epoxy resin. The additive particles may be oxides, for example, the additive particles may include one of or a combination of titanium dioxide (TiO₂), zinc oxide (ZnO), zirconium dioxide (ZrO₂), aluminum oxide (Al₂O₃) and silicon dioxide (SiO₂). Diameters of the additive particles may be about 10 nm to 200 nm, for example, the diameters of the additive particles may be about 20 nm to 100 nm. A mass concentration of the additive particles in the light dispersion layer may be about 5% to 50%, for example, the mass concentration of the additive particles in the light dispersion layer 17 may be about 10% to 40%.

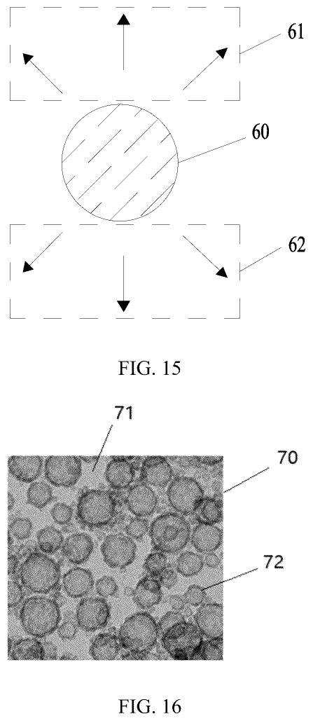

FIG. 15 is a schematic diagram of emergent light after being excited by quantum dots in a color conversion layer in a display panel in accordance with an embodiment of the present disclosure. In an exemplary implementation, as shown in FIG. 15, the emergent light has isotropy after being excited by the quantum dots 60 in the color conversion layer 12, wherein excited photons 61 with a light outgoing direction being 0° to 180° can be emitted along a direction away from the light-emitting substrate, and excited photons 62 with a light outgoing direction being 0° to −180° can be emitted along a direction close to the light-emitting substrate. The excited photons 62 with the light outgoing direction being 0° to −180° cannot be emitted along the direction away from the light-emitting substrate due to waveguide effect in each film layer on one side of the color conversion layer 12 close to the light-emitting substrate, thus causing loss of the light extraction efficiency of the display panel.

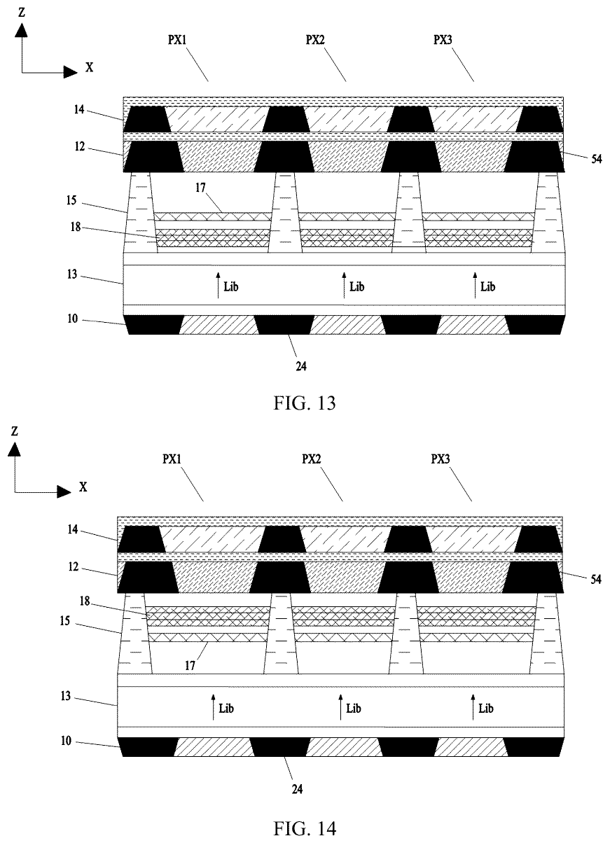

FIG. 13 is a fourth sectional view of a display panel in accordance with an embodiment of the present disclosure. In an exemplary implementation, as shown in FIG. 13, the display panel in accordance with the embodiment of the present disclosure further includes a reflective layer 18 located between the light-emitting substrate 10 and the color conversion layer 12. The reflective layer 18 is partitioned the spacer posts 15 in the first direction X. The reflective layer 18 may be disposed between the first color conversion pattern in the color conversion layer 12 and the first light-emitting device in the light-emitting substrate 10, between the second color conversion pattern in the color conversion layer 12 and the second light-emitting device in the light-emitting substrate 10, and between the light transmission pattern in the color conversion layer 12 and the third light-emitting device in the light-emitting substrate 10.

In the exemplary embodiment, as shown in FIG. 13, the reflective layer 18 is disposed on one side of the light dispersion layer 17 close to the light-emitting substrate 10. The reflective layer 18 is made of a light reflective material. The excited photons with the light outgoing direction being 0° to −180° in the color conversion layer 12 will pass through the light dispersion layer 17 and then be directed towards the reflective layer 18, and the reflective layer 18 is configured to reflect at least a portion of the light directed towards the reflective layer 18 to the color conversion layer 12. The reflective layer 18 can change the light outgoing direction of the excited photons with the light outgoing direction being 0° to −180° in the color conversion layer 12, and reflect the excited photons with the light outgoing direction being 0° to −180° to the color conversion layer 12, thereby improving the light extraction efficiency of the color conversion layer 12 in the display panel in accordance with the present disclosure.

In an exemplary implementation, the reflective layer 18 includes at least one high-refractive-index material layer and at least one low-refractive-index material layer, and the at least one high-refractive-index material layer overlaps with the at least one low-refractive-index material layer along the third direction Z.

In an exemplary implementation, the at least one high-refractive-index material layer may include one of or a combination of titanium dioxide (TiO₂), zirconium dioxide (ZrO₂) and silicon nitride (SiNₓ). A thickness of a high-refractive-index material layer may be about 50 nm to 150 nm, for example, the thickness of the high-refractive-index material layer may be about 60 nm to 100 nm.

In an exemplary implementation, the at least one low-refractive-index material layer may include one of or a combination of aluminum oxide (Al₂O₃), silicon dioxide (SiO₂), magnesium fluoride (MgF₂) and boron oxide (B₂O₃). A thickness of a low-refractive-index material layer may be about 50 nm to 200 nm, for example, the thickness of the low-refractive-index material layer may be about 100 nm to 150 nm.

FIG. 16 is a schematic structural diagram of a low-refractive-index material layer in a display panel in accordance with an embodiment of the present disclosure. In an exemplary implementation, as shown in FIG. 16, the low-refractive-index material layer 70 may include a second matrix 71 and hollow particles 72 disposed in the second matrix 71. The second matrix 71 may be made of an organic material, for example, the second matrix 71 may be made of a silane resin, an epoxy resin, etc. The hollow particles 72 are of core-shell structure, a shell of which may be made of silicon dioxide (SiO₂) and a medium in the shell may be air. A concentration of the hollow particles in the low-refractive-index material layer may be about 10% to 50%, for example, the concentration of the hollow particles in the low-refractive-index material layer may be about 20% to 40%.

In an exemplary implementation, the thickness of the low-refractive-index material layer may be the same as or different from the thickness of the high-refractive-index material layer. Specifically, the thickness of the low-refractive-index material layer and the thickness of the high-refractive-index material layer can be calculated using a formula THK=λ/4n, wherein THK is the thickness of the low-refractive-index material layer or the thickness of the high-refractive-index material layer, λ is a target wavelength, and n is the refractive index of the low-refractive-index material layer or the high-refractive-index material layer.

In an exemplary implementation, a stacking order of the at least one low-refractive-index material layer and the at least one high-refractive-index material layer in the reflective layer 18 depends on the type and concentration of the additive particles in the light dispersion layer 17. Specifically, the additive particles in the light dispersion layer 17 may include one of titanium dioxide (TiO₂), zinc oxide (ZnO) and zirconium dioxide (ZrO₂). A mass concentration of the additive particles in the light dispersion layer 17 is greater than 20%. The reflective layer 18 includes n high-refractive-index material layers and m low-refractive-index material layers, where n is a natural number greater than or equal to 1, m is a natural number greater than or equal to 2, and m is greater than n. A surface of the reflective layer 18 away from the light-emitting substrate 10 is a surface of a low-refractive-index material layer away from the light-emitting substrate, and a surface of the reflective layer 18 close to the light-emitting substrate is a surface of a low-refractive-index material layer close to the light-emitting substrate. For example, a total number of the high-refractive-index material layer(s) and the low-refractive-index material layers in the reflective layer 18 is 3 to 11, and the more the number of the high-refractive-index material layer(s) and the low-refractive-index material layers in the reflective layer 18, the stronger the effect on the reflectivity of light from the color conversion layer 12.

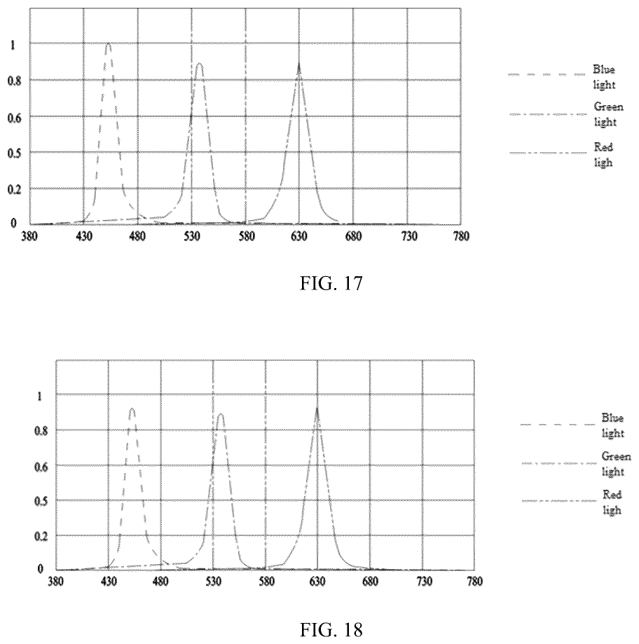

FIG. 17 is a first simulation graph of a display panel in accordance with an embodiment of the present disclosure. FIG. 17 illustrates a graph of simulation results of the display panel in accordance with the embodiment of the present disclosure. The high-refractive-index material layers in the reflective layer 18 of the display panel in accordance with the embodiment of the present disclosure are made of titanium dioxide. A refractive index of the high-refractive-index material layers is 2.5, and a thickness of a high-refractive-index material layer is 60 nm. The low-refractive-index material layers are made of magnesium fluoride. A refractive index of the low-refractive-index material layers is 1.38, and a thickness of a low-refractive-index material layer is 110 nm. A material of the first matrix in the light dispersion layer 17 is titanium dioxide. The reflective layer 18 includes three high-refractive-index material layers and four low-refractive-index material layers, i.e., low-refractive-index material layer/high-refractive-index material layer/low-refractive-index material layer/high-refractive-index material layer/low-refractive-index material layer, which are sequentially stacked along the direction away from the light-emitting substrate. The abovementioned display panel is simulated. As shown in FIG. 17, it may be seen that, according to the simulation results, that the transmittance of blue light is close to 100%, so there is almost no loss of the blue light for the display panel in accordance with the embodiment of the present disclosure. The reflectivities of red light and green light at the dominant wavelengths are 90% and 87% respectively, that is, most of the red light and green light directed towards the reflective layer 18 are reflected by the reflective layer 18, thereby increasing the light extraction efficiency of the display panel.

FIG. 14 is a fifth sectional view of a display panel in accordance with an embodiment of the present disclosure. In an exemplary implementation, as shown in FIG. 16, the reflective layer 18 is disposed on one side of the light dispersion layer 17 away from the light-emitting substrate 10. The reflective layer 18 includes n high-refractive-index material layers and n low-refractive-index material layers, where n is a natural number greater than or equal to 1. A surface of the reflective layer close to the light-emitting substrate is a surface of the high-refractive-index material layer close to the light-emitting substrate, and a surface of the reflective layer away from the light-emitting substrate is a surface of a low-refractive-index material layer away from the light-emitting substrate.

FIG. 18 is a second simulation graph of a display panel in accordance with an embodiment of the present disclosure. FIG. 18 illustrates a graph of simulation results of the display panel in accordance with the embodiment of the present disclosure. The high-refractive-index material layers in the reflective layer 18 of the display panel in accordance with the embodiment of the present disclosure are made of silicon nitride. A refractive index of the high-refractive-index material layers is 1.9, and a thickness of a high-refractive-index material layer is 80 nm. The low-refractive-index material layers are made of silicon dioxide. A refractive index of the low-refractive-index material layers is 1.4, and a thickness of a low-refractive-index material layer is 120 nm. The reflective layer 18 includes four high-refractive-index material layers and four low-refractive-index material layers, i.e., high-refractive-index material layer/low-refractive-index material layer/high-refractive-index material layer/low-refractive-index material layer/high-refractive-index material layer/low-refractive-index material layer/high-refractive-index material layer/low-refractive-index material layer, which are sequentially stacked along a direction away from the light-emitting substrate. The abovementioned display panel is simulated. As shown in FIG. 18, it may be seen, according to the simulation results, that the transmittance of blue light is close to 94%, and the reflectivities of red light and green light at the dominant wavelengths are 91% and 90% respectively, that is, most of the red light and green light directed towards the reflective layer 18 are reflected by the reflective layer 18, thereby increasing the light extraction efficiency of the display panel.

The present disclosure further provides a display apparatus which includes the display panel in accordance with the aforementioned exemplary embodiments. The display apparatus may be any product or component with a display function, such as a mobile phone, a tablet computer, a television, a display, a laptop computer, a digital photo frame or a navigator.

Although the embodiments of the present disclosure are disclosed as above, the contents described are intended for ease of understanding of the embodiments of the present disclosure only, and not to limit the present disclosure. Those skilled in the art may make any modification and alternation to forms and details of implementations without departing from the spirit and scope of the present disclosure. However, the patent protection scope of the present disclosure should still be subject to the scope defined by the appended claims.

1. A display panel, comprising a light-emitting substrate, a light extraction structure layer and a color conversion layer,
wherein the light-emitting substrate is configured to provide incident light to the light extraction structure, the light-emitting substrate comprises at least one light-emitting device;
the light extraction structure layer is located between the light-emitting substrate and the color conversion layer, the light extraction structure layer is configured to form at least a portion of the incident light provided by the light-emitting substrate into collimated light, and emit the collimated light towards the color conversion layer, the light extraction structure layer comprises at least one light extraction pattern, an orthographic projection of a light extraction pattern on a plane where the display panel is located overlaps at least partially with an orthographic projection of a light-emitting device on the plane where the display panel is located, and the light extraction pattern comprises a plurality of protrusions, at least two protrusions in the light extraction pattern have different sizes; and
the color conversion layer is configured to convert the collimated light into light with a specific color, or to transmit the collimated light, the color conversion layer comprises at least one first color conversion pattern, at least one second color conversion pattern and at least one light transmission pattern.

2. The display panel according to claim 1, wherein the at least two protrusions in the light extraction pattern have different shapes.

3. The display panel according to claim 1, wherein a shape of the protrusions comprises at least one of cone, hemisphere or pyramid.

4. The display panel according to claim 1, wherein the plurality of protrusions in the light extraction pattern are arranged in a shape of at least one of a rectangle, a hexagon, a circle, a rhombus, a triangle and a trapezoid.

5. The display panel according to claim 1, wherein a part of the protrusions in the light extraction pattern are arranged along a second direction to form columns of protrusions, the columns of protrusions are arranged along a first direction, protrusions located in a same column of protrusions have a same size, protrusions located in different columns of protrusions have different sizes, and the first direction intersects the second direction.

6. The display panel according to claim 5, wherein the light extraction pattern comprises a first column of protrusions, a second column of protrusions and a third column of protrusions, the first column of protrusions, the second column of protrusions and the third column of protrusions are sequentially arranged along the first direction, protrusions in the first column of protrusions and protrusions in the third column of protrusions have a same size, and a height of protrusions in the second column of protrusions are greater than or less than a height of the protrusions in the first column of protrusions.

7. The display panel according to claim 1, wherein a shape of the orthographic projection of the light-emitting device on the plane where the display panel is located comprises at least one of rectangle, rhombus, hexagon, octagon, circle, triangle and trapezoid.

8. The display panel according to claim 1, wherein the light-emitting substrate comprises at least one first light-emitting device, at least one second light-emitting device and at least one third light-emitting device, an orthographic projection of the at least one first color conversion pattern on the plane where the display panel is located overlaps at least partially with an area where the at least one first light-emitting device is located, an orthographic projection of the at least one second color conversion pattern on the plane where the display panel is located overlaps at least partially with an area where the at least one second light-emitting device is located, and an orthographic projection of the at least one light transmission pattern on the plane where the display panel is located overlaps at least partially with an area where the at least one third light-emitting device is located.

9. The display panel according to claim 1, further comprising spacer posts disposed between the light-emitting substrate and the color conversion layer, and the spacer posts are configured to reflect at least a portion of light directed towards the spacer posts towards the color conversion layer.

10. The display panel according to claim 9, wherein the color conversion layer comprises a light blocking pattern, and an orthographic projection of the spacer posts on the plane where the display panel is located overlaps at least partially with an orthographic projection of the light blocking pattern on the plane where the display panel is located.

11. The display panel according to claim 9, wherein the light-emitting substrate further comprises a pixel definition layer located at a periphery of the light-emitting device, and an orthographic projection of the spacer posts on the plane where the display panel is located is within an orthographic projection of the pixel definition layer on the plane where the display panel is located.

12. The display panel according to claim 9, wherein a cross section of a spacer post in a plane perpendicular to a plane where the light-emitting substrate is located is in a shape of a regular trapezoid or an inverted trapezoid.

13. The display panel according to claim 9, wherein the plurality of the spacer posts, along with the light extraction structure layer and the color conversion layer, form closed chambers, a refractive index of the spacer posts is less than a refractive index of a medium in the closed chambers.

14. The display panel according to claim 1, further comprising a light dispersion layer located between the light-emitting substrate and the color conversion layer, the light dispersion layer is configured to scatter at least a portion of light directed towards the light dispersion layer to form emergent light of uniform intensity, and to emit emergent light towards the color conversion layer.

15. The display panel according to claim 14, wherein the light dispersion layer comprises a first matrix and additive particles disposed in the first matrix, the first matrix is made of an organic material, and the additive particles are made of oxides.

16. The display panel according to claim 15, wherein a diameter of the additive particles is 20 nm to 100 nm, and a mass concentration of the additive particles in the light dispersion layer is 10% to 40%.

17. The display panel according to claim 1, further comprising a reflective layer located between the light-emitting substrate and the color conversion layer, the reflective layer is configured to reflect at least a portion of light directed towards the reflective layer towards the color conversion layer.

18. The display panel according to claim 17, further comprising a light dispersion layer located between the light-emitting substrate and the color conversion layer, the light dispersion layer is configured to scatter at least a portion of light directed towards the light dispersion layer to form emergent light of uniform intensity and emit emergent light towards the color conversion layer, and the reflective layer is disposed on one side of the light dispersion layer close to the light-emitting substrate; or the reflective layer is disposed on one side of the light dispersion layer away from the light-emitting substrate; or
the reflective layer comprises at least one high-refractive-index material layer and at least one low-refractive-index material layer, the at least one high-refractive-index material layer overlaps with the at least one low-refractive-index material layer along a direction perpendicular to the plane where the display panel is located.

19. (canceled)

20. The display panel according to claim 18, wherein the reflective layer is disposed on one side of the light dispersion layer close to the light-emitting substrate, the reflective layer comprises n high-refractive-index material layers and m low-refractive-index material layers, with n being a natural number greater than or equal to 1, m being a natural number greater than or equal to 2, m being greater than n, a surface of the reflective layer away from the light-emitting substrate is a surface of the low-refractive-index material layers away from the light-emitting substrate, and a surface of the reflective layer close to the light-emitting substrate is a surface of the low-refractive-index material layers close to the light-emitting substrate; or
the reflective layer is disposed on one side of the light dispersion layer away from the light-emitting substrate, the reflective layer comprising n high-refractive-index material layers and n low-refractive-index material layers, n being a natural number greater than or equal to 1, a surface of the reflective layer close to the light-emitting substrate is a surface of the high-refractive-index material layers close to the light-emitting substrate, and a surface of the reflective layer away from the light-emitting substrate is a surface of the low-refractive-index material layers away from the light-emitting substrate; or
a low-refractive-index material layer comprises a second matrix and hollow particles disposed in the second matrix, and a concentration of the hollow particles in the low-refractive-index material layer is 20% to 40%; or
the low-refractive-index material layers comprise one of or a combination of aluminum oxide, silicon dioxide, magnesium fluoride and boron oxide; or
the high-refractive-index material layers comprise one of or a combination of titanium dioxide, zirconium dioxide and silicon nitride; or
a thickness of a high-refractive-index material layer is 60 nm to 100 nm, and a thickness of a low-refractive-index material layer is 100 nm to 150 nm.

21-25. (canceled)

26. A display apparatus, comprising the display panel according to claim 1.
